(19) United States
(12) Patent Application Publication
(10) Pub. No.: US 2019/0386613 A1
(43) Pub. Date: Dec. 19, 2019

(54) Electronic Circuit with Tuning Circuit

(71) Applicant: Telefonaktiebolaget LM Ericsson (publ), Stockholm (SE)

(72) Inventor: Anna-Karin Stenman, Hjärup (SE)

(21) Appl. No.: 16/481,625

(22) PCT Filed: Feb. 10, 2017
(86) PCT No.: PCT/EP2017/052997

§ 371 Date: Jul. 29, 2019

(51) Int. Cl. H03B 5/12; H03L 7/099

(52) U.S. Cl. CPC H03B 5/1212; H03L 7/099; H03B 5/1253

(57) ABSTRACT

A differential electronic circuit (25) comprising a tuning circuit (140, 140-i) connected between a first circuit node (110) and a second circuit node (112) of the electronic circuit (25), is disclosed. The tuning circuit (140, 140-i) comprises at least one controllable circuit (150, 150-i), each comprising a first MOS transistor (152) having its drain and source connected to a common node in (156) of the controllable circuit (150, 150-i) and its gate connected to a first internal node (158) of the tuning circuit (140, 140-i), and a second MOS transistor (154) having its drain and source connected to the common node (156) of the controllable circuit (150, 150-i) and its gate connected to a second internal node (160) of the tuning circuit (140, 140-i). The tuning circuit comprises a first capacitor (170) operatively connected between the first circuit node (110) and the first internal node (158) of the tuning circuit (140, 140-i) and a second capacitor (172) operatively connected between the second circuit node (112) and the second internal node (160) of the tuning circuit (140, 140-i), and a control circuit (180) configured to provide a variably controllable bias voltage to the first and the second internal nodes (158, 160) of the tuning circuit (140, 140-i) and, to each controllable circuit (150, 150-i), a digitally controllable tuning voltage to the common node (156) of the controllable circuit (150, 150-i). An electronic apparatus and a method are also disclosed.

### TECHNICAL FIELD

The present invention relates to an electronic circuit, such as an oscillator circuit, comprising a tuning circuit.

### BACKGROUND

In for example cellular communications equipment, such as mobile phones (or other wireless devices) and radio base stations, oscillator circuits are used to generate local-oscillator (LO) signals for transceiver circuits. The oscillator circuit is typically part of a frequency synthesizer, such as a phase-locked loop (PLL), in which the oscillator is tuned to generate the correct frequency. An example of such a PLL is an all-digital PLL (ADPLL) which uses a digitally-controlled oscillator (DCO) circuit.

One common solution for a high frequency oscillator utilizes a cross coupled common source core, and a tunable tank circuit comprising a fixed metal inductor and a variable capacitor. The variable capacitor may be implemented with a back-to-back connected pair of MOS varactors. An example of this is presented in A. I. Hussein, S. Saberi and J. Paramesh, “A 10 mW 60 GHz 65 nm CMOS DCO with 24% tuning range and 40 kHz frequency granularity,” Custom Integrated Circuits Conference (CICC), 2015 IEEE, San Jose, Calif., 2015, pp. 1-4. In a DCO circuit, the variable capacitor may be implemented with a plurality of such pairs of MOS varactors connected in parallel, forming a capacitor bank. Each pair of MOS varactors may be controlled with a single-bit control signal, determining a control voltage of that pair of MOS varactors to be either a first voltage or a second voltage depending on the value of the single-bit control signal. The capacitor bank would thus be controlled by multiple such single-bit control signals, forming a multi-bit tuning word.

In for instance future fifth generation (5G) cellular systems, it is suggested to make use of relatively high frequency ranges, such as in the order of 20-40 GHz. In such applications, the frequency synthesizer may need to provide a relatively wide frequency tuning range, and may also need to provide relatively high spectral purity. It should be noted that other circuits than oscillators, such as filters, may require tuning as well.

### SUMMARY

The inventor has realized that an improved controllability of an oscillator circuit can be obtained by providing controllable voltages at both the gate nodes and the drain/source nodes of the MOS varactors. For example, this allows the use of different capacitance tuning steps in different frequency ranges. This, in turn, enables controllability of the frequency tuning steps of the oscillator in different frequency ranges. For example, the oscillator can be controlled to have a relatively constant frequency tuning step over a number of different frequency ranges. This tuning technique can be applied to other tunable circuits which utilizes tunable MOS varactors for their tunability as well, such as but not limited to filter circuits.

According to a first aspect, there is provided a differential electronic circuit comprising a tuning circuit connected between a first circuit node and a second circuit node of the electronic circuit. The tuning circuit comprises at least one controllable circuit. Each controllable circuit comprises a first MOS transistor having its drain and source connected to a common node of the controllable circuit and its gate connected to a first internal node of the tuning circuit and a second MOS transistor having its drain and source connected to the common node of the controllable circuit and its gate connected to a second internal node of the tuning circuit. The tuning circuit comprises a first capacitor operatively connected between the first circuit node and the first internal node of the tuning circuit and a second capacitor operatively connected between the second circuit node and the second internal node of the tuning circuit. Furthermore, the tuning circuit comprises a control circuit configured to provide a variably controllable bias voltage to the first and the second internal nodes of the tuning circuit and, to each controllable circuit, a digitally controllable tuning voltage to the common node of the controllable circuit.

The control circuit may comprise a digital-to-analog converter configured to generate the variably controllable bias voltage.

The electronic circuit may comprise a first resistor connected between the first internal node of the tuning circuit and an output of the digital-to-analog converter and a second resistor connected between the second internal node of the tuning circuit and the output of the digital-to-analog converter.

In some embodiments, the digitally controllable tuning voltage is controllable via a single bit.

In some embodiments, the at least one controllable circuit is a single controllable circuit. In other embodiments, the at least one controllable circuit is a plurality of controllable circuits.

The electronic circuit may comprise a plurality of tuning circuits connected in parallel.

The electronic circuit may be an oscillator circuit. The oscillator circuit may be a digitally-controlled oscillator.

According to a second aspect, there is provided an electronic apparatus comprising the electronic circuit of any preceding claim. The electronic apparatus may be a communication apparatus. The communication apparatus may for instance be a wireless device configured to operate in a cellular communications system or a base station configured to operate in a cellular communications system.

According to a third aspect, there is provided a method of controlling the electronic circuit of the first aspect, wherein the electronic circuit in this case is an oscillator circuit. The method comprises selecting a frequency range in which the oscillator circuit is to operate among a plurality of frequency ranges in which the oscillator circuit is capable of operating. Furthermore, the method comprises setting the variably controllable bias voltage based on the selected frequency range. Moreover, the method comprises controlling the digitally controllable tuning voltages of the controllable circuits to tune the frequency of the oscillator circuit within the selected frequency range.

In some embodiments, for a first frequency range and a second frequency range, having a higher center frequency than the first frequency range, setting the variably controllable bias voltage comprises setting the variably controllable bias voltage such that an absolute capacitance tuning step size of the tuning circuit, when changing the digitally controllable tuning voltage of a controllable circuit from a first voltage level to a second voltage level, is higher for the first frequency range than for the second frequency range.

The electronic circuit of the first aspect or the electronic apparatus of the second aspect may comprise control circuitry configured to perform the method of the third aspect.

Further embodiments are defined in the dependent claims. It should be emphasized that the term “comprises/comprising” when used in this specification is taken to specify the presence of stated features, integers, steps, or components, but does not preclude the presence or addition of one or more other features, integers, steps, components, or groups thereof.

### BRIEF DESCRIPTION OF THE DRAWINGS

Further objects, features and advantages of embodiments of the invention will appear from the following detailed description, reference being made to the accompanying drawings, in which:

FIG. 1 illustrates a communication environment.

FIG. 2 illustrates a transceiver circuit.

FIGS. 3-7 are circuit diagrams.

FIGS. 8-9 illustrate embodiments of a method.

FIG. 10 shows simulation results.

### DETAILED DESCRIPTION

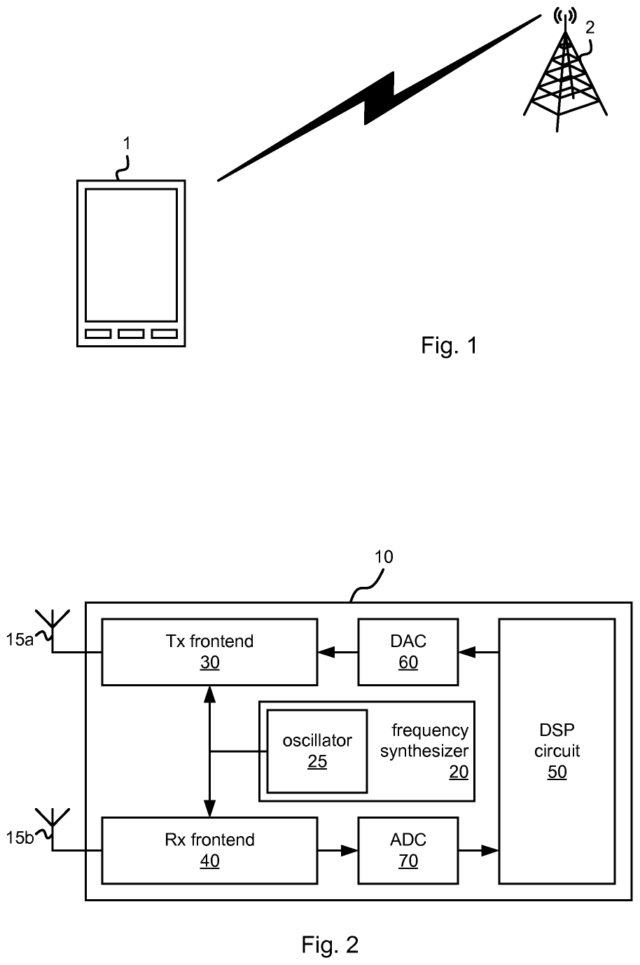

FIG. 1 illustrates a communication environment wherein embodiments of the present invention may be employed. A wireless device 1 of a cellular communications system is in wireless communication with a radio base station 2 of the cellular communications system. The wireless device 1 may be what is generally referred to as a user equipment (UE). The wireless devices 1 is depicted in FIG. 1 as a mobile phone, but may be any kind of device with cellular communication capabilities, such as a tablet or laptop computer, machine-type communication (MTC) device, or similar. Furthermore, a cellular communications system is used as an example throughout this disclosure. However, embodiments of the present invention may be applicable in other types of systems as well, such as but not limited to WiFi systems.

The radio base station 2 and wireless device 1 are examples of what in this disclosure is generically referred to as communication apparatuses. Embodiments are described below in the context of a communication apparatus in the form of the radio base station 2 or wireless device 1. However, other types of communication apparatuses can be considered as well, such as a WiFi access point or WiFi enabled device.

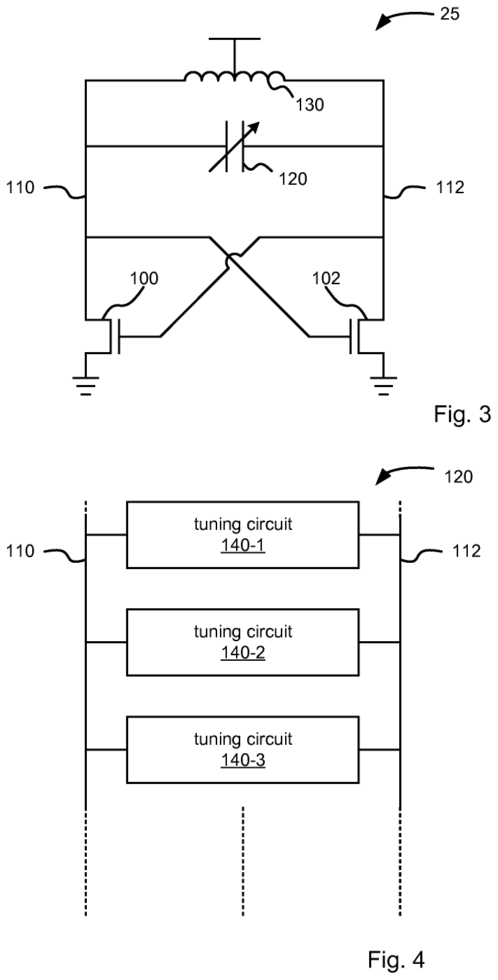

FIG. 2 illustrates a simplified block diagram of a transceiver circuit 10, which may e.g. be comprised in any of the communication apparatuses 1 or 2. In FIG. 2, the transceiver circuit 10 is configured to transmit signals via a transmit antenna 15a and receive signals via a receive antenna 15b. It should be noted that this is merely an example. Various other antenna arrangements are possible as well, including multiple transmit or receive antennas, or one or more shared transmit and receive antennas. Furthermore, in FIG. 2, the transceiver circuit comprises a frequency synthesizer 20, such as a phase-locked loop (PLL). The frequency synthesizer 20 comprises an oscillator 25. The oscillator 25 is configured to generate a local oscillator (LO) signal to a transmitter frontend circuit 30, connected to the transmit antenna 15a, and/or a receiver frontend circuit 40, connected to the receive antenna 15b. The LO signal may e.g. be used for driving mixer circuits in the transmitter frontend circuit 30 or the receiver frontend circuit. In FIG. 2, the transceiver circuit 10 comprises a digital signal processing (DSP) circuit 50, such as a baseband processor. The DSP circuit 50 is configured to generate signals to be transmitted and process received signals in the digital domain. The transceiver circuit 10 further comprises a digital-to-analog converter (DAC) 60 configured to convert signals to be transmitted generated by the DSP circuit 50 from a digital to an analog representation, and provide the analog representation to the transmitter frontend 30 for transmission. Moreover, the transceiver circuit 10 comprises an analog-to-digital converter (ADC) 70 configured to convert signals received via the receiver frontend 40 from an analog to a digital representation and provide the digital representation to the DSP circuit 50 for processing therein.

Throughout this disclosure, the oscillator circuit 25 is used as an example for the application of a tuning circuit. It should be noted, however, that the tuning circuit according to embodiments may be used also in other types of tunable electronic circuits that rely on tuning a capacitance for tunability, such as filters with tunable capacitors. The tuning circuits and electronic circuits, such as oscillators, described herein can be beneficially integrated on an integrated circuit. Furthermore, the communication apparatuses 1 and 2 are used as examples herein, but said electronic circuit may be comprised in other types of electronic apparatuses as well.

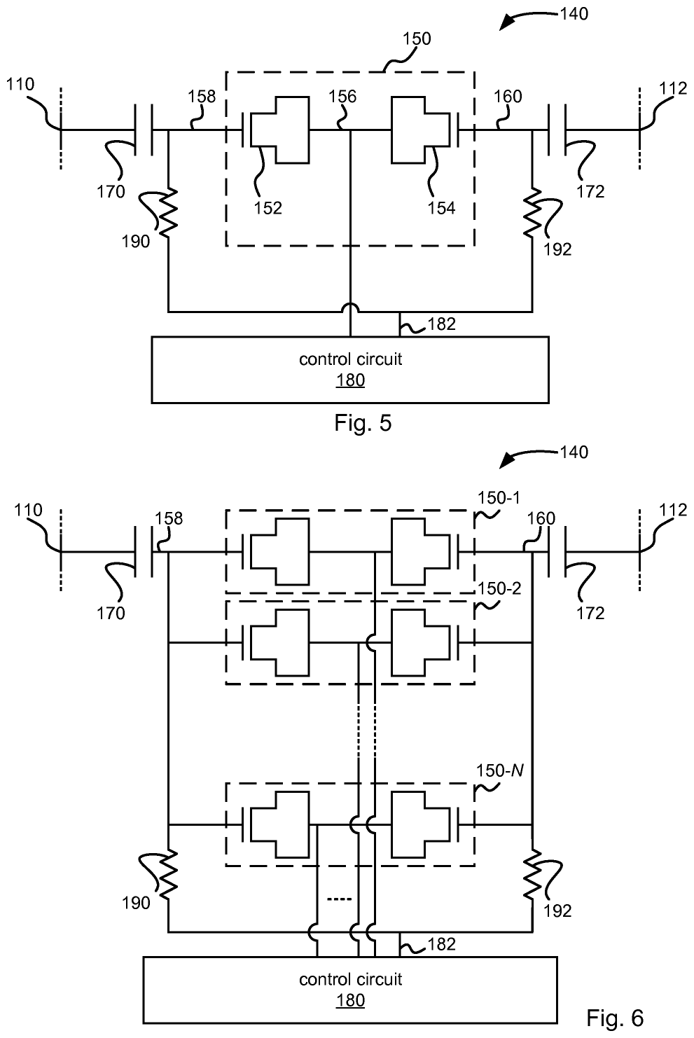

FIG. 3 shows a simplified circuit diagram of an embodiment of the oscillator circuit 25. In the embodiment illustrated in FIG. 3, the oscillator circuit 25 is a differential oscillator circuit It comprises a cross coupled pair of transistors, in this case NMOS transistors, 100 and 15 102. The gate of transistor 102 and drain of transistor 100 are connected to a first circuit node 110. Similarly, the gate of transistor 100 and drain of transistor 102 are connected to a second circuit node 112.

Furthermore, according to the embodiment illustrated in FIG. 3, the oscillator circuit 25 comprises an inductor 130 connected between the first circuit node 110 and the second circuit node 112. Moreover, according to the embodiment illustrated in FIG. 3, the oscillator circuit comprises a tunable capacitor 120 connected between the first circuit node 110 and the second circuit node 112. As is readily appreciated by the skilled person, the capacitor 120 and inductor 130 forms a resonant tank circuit. The resonance frequency of this resonant tank circuit, and thereby the oscillation frequency of the oscillator circuit 25, can be tuned by tuning the tunable capacitor 120. It should be noted that the oscillator topology in FIG. 4 is merely an example. Various other oscillator circuit topologies comprising a tunable capacitor for tuning the oscillation frequency of the oscillator circuit exist and may be used as well in other embodiments.

FIG. 4 illustrates an embodiment of the tunable capacitor 120. As illustrated in FIG. 4, one or more tuning circuits 140-i, described in more detail below, are connected between the first circuit node 110 and the second circuit node 112. FIG. 4 shows three tuning circuits 140-1, 140-2, and 140-3. However, as indicated by the dotted lines, more tuning circuits 140-i may be included, but also fewer, such as one or two. It should be noted that the tunable capacitor 120 may comprise additional circuitry (not shown) with tunable capacitance, other than the tuning circuits 140-i. The other circuitry may e.g. be responsible for a coarse tuning of the tunable capacitor 120. The tuning circuits 140-i may be responsible for fine tuning of the tunable capacitor 120. Alternatively or additionally, one or more of the tuning circuits 140-i may be responsible for the coarse tuning, whereas one or more of the other tuning circuits 140-i may be responsible for the fine tuning

FIG. 5 illustrates an embodiment of a tuning circuit 140. Any one of the tuning circuits 140-i in FIG. 4 may be implemented as the tuning circuit 140 in FIG. 5. In FIG. 5, the tuning circuit 140 comprises a controllable circuit 150. The controllable circuit 150 comprises a first MOS transistor 152 and a second MOS transistor 154. The first MOS transistor 152 has its drain and source connected to a common node 156 of the controllable circuit 150 and its gate connected to a first internal node 158 of the tuning circuit 140. The second MOS transistor 154 has its drain and source connected to the common node 156 of the controllable circuit 150 and its gate connected to a second internal node 160 of the tuning circuit 140. The tuning circuit 140 in FIG. 5 also comprises a first capacitor 170 and a second capacitor 172. The first capacitor 170 is operatively connected between the first circuit node 110 and the first internal node 158 of the tuning circuit 140. The second capacitor 172 is operatively connected between the second circuit node 112 and the second internal node 160 of the tuning circuit 140. The capacitors 170 and 172 isolate the internal nodes 158 and 160 from the circuit nodes 110 and 112, respectively, from a DC (direct current) perspective, and allow the internal nodes to be DC biased independently of the DC level of the circuit nodes 110 and 112. Accordingly, as illustrated in FIG. 5, the tuning circuit 140 comprises a control circuit 180 configured to provide a variably controllable bias voltage to the first and the second internal nodes 158, 160 of the tuning circuit 140. In FIG. 5, this bias voltage is provided via an output 182 of the control circuit 180. Thereby, the control circuit 180 controls the DC bias level at these nodes. In FIG. 5, this bias voltage is provided via an output 182 of the control circuit 180. Furthermore, in FIG. 5, the tuning circuit comprises resistors 190 and 192, connected between the output 182 and the internal nodes 158 and 160, respectively. These resistors serve to isolate the internal nodes 158 and 160, AC (Alternating Current) wise, from the output 182.

The control circuit 18 is also configured to provide a digitally controllable tuning voltage to the common node 156 of the controllable circuit 150. It should be noted that the terms “bias voltage” (provided to the internal nodes 158 and 160) and “tuning voltage” (provided to the common node 156) are used as labels in this context to identify and separate the two voltages in the text and not confuse them with each other. However, they both serve to bias and to tune the capacitance of the tuning circuit 140.

According to some embodiments, the tuning voltage is controlled via a single digital control bit, referred to in the following as the tuning bit, and can thus adopt one of two possible values, one ‘high’ voltage (e.g. when the tuning bit is ‘1’) and one low' voltage (e.g. when the tuning bit is ‘0’). The tuning circuit 140 thus effectively has two states, which we can refer to as a ‘1’-state (e.g. when the tuning bit is ‘1’), providing a first capacitance between the circuit nodes 110 and 112, and a ‘0’-state (e.g. when the tuning bit is ‘0’) providing a second capacitance between the circuit nodes 110 and 112. We refer to the difference between the first and second capacitance values as the unit capacitance step ΔC. The bias voltage gives a further degree of control over the tuning circuit 140. By varying the bias voltage, the unit capacitance step ΔC can be varied. It should be noted that when MOS transistors 152 and 154 are NMOS transistors, the second capacitance is higher than the first capacitance, and thus ΔC is negative. If PMOS transistors are used instead, then the first capacitance would be higher than the second capacitance, and thus ΔC would be positive.

In FIG. 5, the tuning circuit 140 comprises a single controllable circuit 150. In other embodiments, the tuning circuit 140 comprises a plurality of controllable circuits in parallel. This is illustrated in FIG. 6, showing a plurality of controllable circuits 150-1, . . . , 150-N, each connected between the internal nodes 158 and 160 of the tuning circuit 140. In this embodiment, the control unit 180 may be adapted to provide individual digitally controllable tuning voltages to the common node of each controllable circuit 150-i. This is illustrated in FIG. 6 with individual control connections between the control circuit 180 and the common node of each controllable circuit 150-i.

According to some embodiments, similar to what is described above, each of the individual tuning voltages is controlled via an individual single digital control bit, again referred to as tuning bit, and can thus adopt one of two possible values, one ‘high’ voltage (e.g. when the tuning bit is ‘1’) and one low' voltage (e.g. when the tuning bit is ‘0’). Together, these individual tuning bits form a multibit tuning word of the tuning circuit. Similar to the embodiment described above with reference to FIG. 5, we refer to the difference in capacitance of the tuning circuit 140 between two consecutive tuning words as the unit capacitance step ΔC. As above, the bias voltage gives a further degree of control over the 30 tuning circuit 140. By varying the bias voltage, the unit capacitance step ΔC can be varied.

More generally, as outlined above, above, a differential electronic circuit 25 (which may be an oscillator, but also some other kind of tunable electronic circuit) may comprise one or more tuning circuits 140-i, as described above, each connected between a first circuit node 110 and a second circuit node 112 of the electronic circuit 25.

In some embodiments, the variably controllable bias voltage is a digitally controllable bias voltage. According to some such embodiments, the control circuit 180 may comprise a digital-to-analog converter configured to generate the variably controllable bias voltage from a digital control word. Any type of digital-to-analog converter may be used for this purpose. A relatively simple and efficient implementation can be obtained using a resistor-string digital-to-analog converter, which is illustrated with an example in FIG. 7. A resistor string of series-connected resistors 201-209 is connected between two well-defined voltages, such as a supply voltage and ground. A number of different voltages are thereby generated at the interconnecting nodes between the resistors 201-209. If the resistors 202-208 are implemented with equal resistance, the generated voltages are equidistant. The resistances of the end resistors 201 and 209 can be selected, together with the resistance of resistors 202-208 to give suitable end-point voltages (i.e. the voltage between resistors 201 and 202 and the voltage between resistors 208 and 209). Resistive voltage division is well known to persons skilled in the art of analog electronics and is not further described herein.

Switches 211-218, effectively forming a multiplexer, are connected between the interconnecting nodes between the resistors and the output 182. Switch 211 is connected to the node between resistors 201 and 202. Switch 212 is connected to the node between resistors 202 and 203. Switch 213 is connected to the node between resistors 203 and 204. Switch 214 is connected to the node between resistors 204 and 205. Switch 215 is connected to the node between resistors 205 and 206. Switch 216 is connected to the node between resistors 206 and 207. Switch 217 is connected to the node between resistors 207 and 208. Switch 218 is connected to the node between resistors 208 and 209. An N-bit digital-to-analog converter has 2′ different input words and voltage levels. The digital-to-analog converter in FIG. 7 has eight different voltage levels and is thus a three-bit digital-to-analog converter. The switches 211-218 can be controlled via a three-bit input word such that one of the switches 211-218 is closed, and the others are open, as indicated in the table below.

| input word | closed switch |
|---|---|
| 000 | 211 |
| 001 | 212 |
| 010 | 213 |
| 011 | 214 |
| 100 | 215 |
| 101 | 216 |
| 110 | 217 |
| 111 | 218 |

Implementing control logic for such functionality is a straight-forward task for a person skilled in electronic design and is not further discussed herein. It should be noted that the three-bit digital-to-analog converter is merely an example. The number of bits may be selected depending on the requirements of the particular implementation.

It should be noted that the example illustrated above with reference to FIG. 7 is merely an example and not intended to be limiting. Other alternatives, analog or digital, for generating the variably controllable bias voltage are possible as well.

According to some embodiments, the oscillator circuit 25 is a digitally-controlled oscillator (DCO). Such DCOs may beneficially be comprised in a digitally controlled frequency synthesizer, such as a digital PLL.

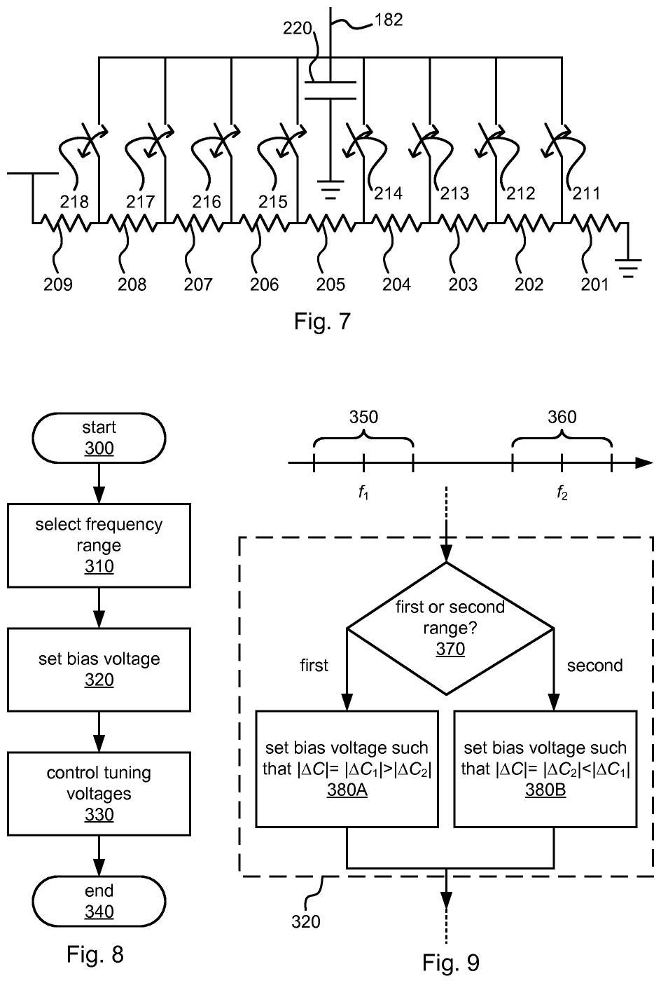

A method of controlling the oscillator 25 is described below with reference to FIGS. 8-9. In some embodiments, the control circuit 180 is configured to perform the method. In other embodiments, the electronic apparatus or electronic circuit may comprise some other control circuitry, such as the DSP circuit 50, configured to perform the method. Consider first the embodiment of the oscillator circuit illustrated in FIG. 3 and let L denote the inductance of the inductor 130 and let C denote the variable capacitance of capacitor 120. The oscillation angular frequency of the oscillator is approximately given by

$$ω = \frac{1}{\sqrt{LC}} = {L}^{- \frac{1}{2}} {C}^{- \frac{1}{2}} \qquad Eq . 1$$

It follows that

$$\frac{\partial ω}{\partial C} = - \frac{1}{2} {L}^{- \frac{1}{2}} {C}^{- \frac{3}{2}} = - \frac{1}{2} L ( {L}^{- \frac{3}{2}} {C}^{- \frac{3}{2}} ) = - \frac{1}{2} L {ω}^{2} \qquad Eq . 2$$

Let ωₙ denote the angular frequency for a given capacitance Cₙ. The corresponding change, or unit step, in angular frequency, Δω, when C is changed with a unit capacitance step ΔC from Cₙ, to Cₙ+ΔC, is

$$Δ ω \approx \frac{\partial ω}{\partial C} {\vert}_{C = {C}_{n}} Δ C = - \frac{1}{2} L {ω}_{n}^{3} Δ C \qquad Eq . 3$$

Hence, for a fixed ΔC, the unit step in angular frequency Δω depends on the angular frequency. Hence, for a relatively wide tuning range for the oscillator 25, the unit step in angular frequency Δω may be considerably different in one end of the tuning range than in the other. In some applications, it may be desirable to have approximately the same Δω over the whole tuning range. For example, the overall tuning range may be divided into a number of frequency ranges in which the oscillator circuit 25 is capable of operating. Such frequency ranges may e.g. correspond to different communication frequency bands which the oscillator circuit 25 could be tuned to. Alternatively, the frequency ranges may be sub ranges of a larger frequency range. The larger frequency range may correspond to communication frequency band within which the oscillator circuit 25 could be tuned to operate in. It may be desirable to have the same Δω for all those frequency ranges. Alternatively, it may be desirable to be able to control Δω individually for the different frequency ranges. Both these options are made possible by means of the variably controllable bias voltage described herein, through which it is possible to control ΔC, and thereby to control Δω. How to control ΔC as a function of angular frequency ω to obtain a desired Δω can be derived from Eq. 3. For example, to obtain a relatively constant Δω over the whole tuning range, ΔC should vary proportionally with ω⁻³. The value of ΔC can also be derived in terms of the inductance L and capacitance C. It can be derived from Eq. 3 that

|ΔC|=2|Δω|L^{1/2}C^{3/2} Eq. 4

Equivalently, if frequency f is preferred over angular frequency ω=2πf,

|ΔC|=4π|Δf|L^{1/2}Cₙ^{3/2} Eq. 5

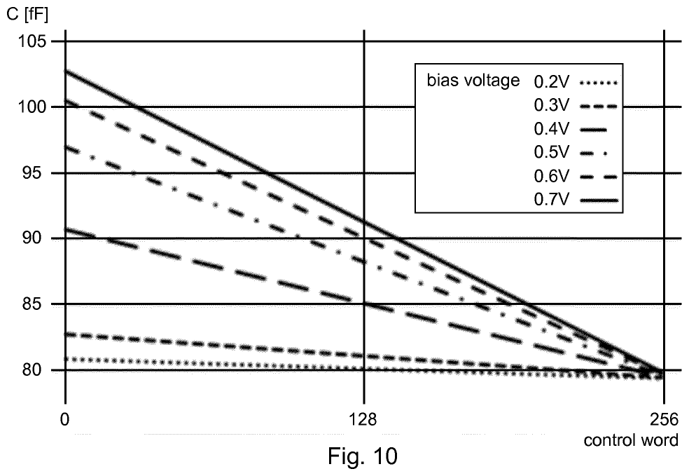

What bias voltage to use to obtain a certain ΔC can e.g. be derived using transistor-level 30 computer simulations, for instance as shown below with reference to FIG. 10.

Qualitatively speaking, by means of the variably controllable bias voltage, it is thus possible to, in some embodiments, to obtain a relatively fine, or small, frequency tuning step for fine tuning at higher frequencies, while at the same time maintain a relatively wide frequency tuning range for fine tuning at lower frequencies.

An embodiment of the method of controlling the oscillator circuit 25 is shown in FIG. 8. The operation is started in step 300. In line with what is discussed above, the method comprises step 310 of selecting a frequency range in which the oscillator circuit 25 is to operate among a plurality of frequency ranges in which the oscillator circuit 25 is capable of operating. Furthermore, the method comprises step 320 of setting the variably controllable bias voltage based on the selected frequency range. The selection may e.g. be based on a center frequency, or angular frequency, of the frequency range to obtain a desired Δω. The method further comprises the step 330 of controlling the digitally controllable tuning voltages of the controllable circuits 150, 150-i to tune the frequency of the oscillator circuit 25 within the selected frequency range. That is, when adjustments of the oscillation frequency is needed within said frequency range, it is effectuated by changing the digitally controllable tuning voltages, e.g. by adjusting the above-mentioned tuning word, while the variably controllable bias voltage is kept constant, e.g. to obtain a desired Δω. The operation is ended in step 340. The method may e.g. be repeated each time the oscillator circuit 25 should be tuned to a new frequency range.

FIG. 9 illustrates an example with a first frequency range 350 with a center frequency f₁, and a second frequency range 360 with a center frequency f₂. The frequency ranges 350 and 360 may be sub ranges of a larger frequency range. In the example illustrated in FIG. 9, the first frequency range 350 and the second frequency range 360 are disjoint, but this is not necessary in all embodiments. However, it simplifies the illustration. Furthermore, f₂>f₁. To counteract the dependence of

$$\frac{\partial ω}{\partial C}$$

on ω³, which, for a fixed ΔC, would give increasingly larger Δω for increasing ω, |ΔC| can be selected higher for the first frequency range than for the second frequency range. For example, as mentioned above, ΔC can be selected inversely proportional to the cube of the center frequency of the frequency range.

A flowchart of step 320 illustrating this is shown in FIG. 9 as well. In this embodiment step 320 comprises setting the variably controllable bias voltage such that a capacitance tuning step size, such as ΔC, of the tuning circuit 140, 140-i, when changing the digitally controllable tuning voltage of a controllable circuit 150, 150-i from a first voltage level to a second voltage level, is higher for the first frequency range 350 than for the second frequency range 360. In step 370, it is checked whether the first frequency range 350 or the second frequency range 360 should be used. If it is the first frequency range 350, the operation proceeds to step 380A. If it is the second frequency range 360, the operation proceeds to step 380B. In step 380A, variably controllable bias voltage is set such that ΔC=ΔC₁. In step 380B, variably controllable bias voltage is set such that ΔC=ΔC₂, where |ΔC₁|>|ΔC₂|.

It should be noted that the variably controllable bias voltage may be set (e.g. in step 380A or 380B) by first setting it to an initial value, e.g. based on a table look-up or a previously used value stored in a memory. The variably controllable bias voltage may then be calibrated to obtain a desired step size, e.g. for Δω or ΔC.

It should also be noted that even though the example mentions two frequency ranges 360 and 370, this does not exclude that there are more than two frequency ranges in some embodiments. For example, there may be a third frequency range (not shown) with center frequency f₃, where f₁<f₃<f₂. If this third frequency range should be used, the variably controllable bias voltage may be set such that ΔC=ΔC₃, where |ΔC₁|>|ΔC₂|.

FIG. 10 illustrate simulation examples of a tuning circuit of the type illustrated in FIG. 6, having 256 identically sized controllable circuits 150-1, 150-2, . . . , 150-256. The x axis represents the tuning word, and shows the number of controllable circuits 150-i for which the digitally-controllable tuning voltage is high. The y axis represents the absolute capacitance. The different curves show different capacitive tuning ranges as a function of the variably controllable bias voltage. Results for values of the variably controllable bias voltage 0.2 V to 0.7 V in 0.1 V steps are plotted. The quantitative values shown naturally depends on the sizing of components and what integrated circuit manufacturing technology is used. However, the qualitative behavior shown in FIG. 10 remains valid irrespective of these factors. The slopes of the lines in FIG. 10 corresponds to ΔC.

The present invention has been described above with reference to specific embodiments. However, other embodiments than the above described are possible within the scope of the 25 disclosure. The different features and steps of the embodiments may be combined in other combinations than those described.

1-15 (canceled)

16. A differential electronic circuit comprising a tuning circuit connected between a first circuit node and a second circuit node of the differential electronic circuit, wherein the tuning circuit comprises:
at least one controllable circuit, each comprising:
a first MOS transistor having its drain and source connected to a common node of the controllable circuit and its gate connected to a first internal node of the tuning circuit; and
a second MOS transistor having its drain and source connected to the common node of the controllable circuit and its gate connected to a second internal node of the tuning circuit;
a first capacitor operatively connected between the first circuit node and the first internal node of the tuning circuit;
a second capacitor operatively connected between the second circuit node and the second internal node of the tuning circuit; and
a control circuit configured to provide a variably controllable bias voltage to the first and the second internal nodes of the tuning circuit and, to each controllable circuit, a digitally controllable tuning voltage to the common node of the controllable circuit.

17. The differential electronic circuit of claim 16, wherein the control circuit comprises a digital-to-analog converter configured to generate the variably controllable bias voltage.

18. The differential electronic circuit of claim 17, comprising:
a first resistor connected between the first internal node of the tuning circuit and an output of the digital-to-analog converter; and
a second resistor connected between the second internal node of the tuning circuit, and the output of the digital-to-analog converter.

19. The differential electronic circuit of claim 16, wherein the digitally controllable tuning voltage is controllable via a single bit.

20. The differential electronic circuit of claim 16, wherein the at least one controllable circuit is a single controllable circuit.

21. The differential electronic circuit of claim 16, wherein the at least one controllable circuit is a plurality of controllable circuits.

22. The differential electronic circuit of claim 16, comprising a plurality of tuning circuits connected in parallel.

23. The differential electronic circuit of claim 16, wherein the differential electronic circuit is an oscillator circuit.

24. The differential electronic circuit of claim 23, wherein the oscillator circuit is a digitally-controlled oscillator.

25. An electronic apparatus comprising a differential electronic circuit, wherein the differential electronic circuit comprises a tuning circuit connected between a first circuit node and a second circuit node of the differential electronic circuit, wherein the tuning circuit comprises:
at least one controllable circuit, each comprising:
a first MOS transistor having its drain and source connected to a common node of the controllable circuit and its gate connected to a first internal node of the tuning circuit; and
a second MOS transistor having its drain and source connected to the common node of the controllable circuit and its gate connected to a second internal node of the tuning circuit;
a first capacitor operatively connected between the first circuit node and the first internal node of the tuning circuit;
a second capacitor operatively connected between the second circuit node and the second internal node of the tuning circuit; and
a control circuit configured to provide a variably controllable bias voltage to the first and the second internal nodes of the tuning circuit and, to each controllable circuit, a digitally controllable tuning voltage to the common node of the controllable circuit.

26. The electronic apparatus of claim 25, wherein the electronic apparatus is a communication apparatus.

27. The electronic apparatus of claim 26, wherein the communication apparatus is a wireless device configured to operate in a cellular communications system.

28. The electronic apparatus of claim 26, wherein the communication apparatus is a base station configured to operate in a cellular communications system.

29. The electronic apparatus of claim 26, wherein the control circuit comprises a digital-to-analog converter configured to generate the variably controllable bias voltage.

30. The electronic apparatus of claim 26, the differential electronic circuit comprising:
a first resistor connected between the first internal node of the tuning circuit and an output of the digital-to-analog converter; and
a second resistor connected between the second internal node of the tuning circuit, and the output of the digital-to-analog converter.

31. The electronic apparatus of claim 26, wherein the digitally controllable tuning voltage is controllable via a single bit.

32. The electronic apparatus of claim 26, wherein the differential electronic circuit is an oscillator circuit.

33. The electronic apparatus of claim 32, wherein the oscillator circuit is a digitally-controlled oscillator.

34. A method of controlling an oscillator circuit that comprises a tuning circuit connected between a first circuit node and a second circuit node of the oscillator circuit, the tuning circuit comprising at least one controllable circuit, each comprising a first MOS transistor and a second MOS transistor, the first MOS transistor having its drain and source connected to a common node of the controllable circuit and its gate connected to a first internal node of the tuning circuit, and the second MOS transistor having its drain and source connected to the common node of the controllable circuit and its gate connected to a second internal node of the tuning circuit, the method comprising:
selecting a frequency range in which the oscillator circuit is to operate among a plurality of frequency ranges in which the oscillator circuit is capable of operating;
setting, based on the selected frequency range, a variably controllable bias voltage that is provided to the first and second internal nodes of the tuning circuit; and
controlling a digitally controllable tuning voltage of each controllable circuit to tune the frequency of the oscillator circuit within the selected frequency range, wherein the digitally controllable tuning voltage of each controllable circuit is provided to the common node of the controllable circuit.

35. The method of claim 34, wherein, for a first frequency range and a second frequency range, having a higher center frequency than the first frequency range, setting the variably controllable bias voltage comprises
setting the variably controllable bias voltage such that an absolute capacitance tuning step size of the tuning circuit, when changing the digitally controllable tuning voltage of a controllable circuit from a first voltage level to a second voltage level, is higher for the first frequency range than for the second frequency range.
